(19) United States
(12) Patent Application Publication
(10) Pub. No.: US 2002/0037472 A1
(43) Pub. Date: Mar. 28, 2002

(54) Novel polymers and photoresist compositions comprising labile polymer backbones for short wave imaging

(75) Inventors: Anthony Zampini, Westborough, MA (US); Sungseo Cho, Milford, MA (US); Peter Trefonas III, Medway, MA (US)

Correspondence Address: Peter F. Corless, EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 09/948,389

(22) Filed: Sep. 8, 2001

Related U.S. Application Data
(60) Provisional application No. 60/231,392, filed on Sep. 8, 2000.

(51) Int. Cl. G03F 7/038; G03F 7/039; G03F 7/30

(52) U.S. Cl. 430/270.1; 430/325; 430/326; 430/272.1

(57) ABSTRACT

The present invention includes polymers and photoresist compositions that comprise the polymers as a resin binder component. Photoresists of the invention include chemically-amplified positive-acting resists that can be effectively imaged at short wavelengths such as sub-300 nm, particularly 157 nm. Preferred polymers and photoresists include acid labile acetal or ketal groups that help degrade the polymer by hydrolysis. More preferred polymers include at least one electronegative group that reduces or avoids 157 nm absorbance of a wide spectrum of organic groups including aromatic groups such as phenolic moieties.

### BACKGROUND OF THE INVENTION

1. Field of the Invention

The present invention relates to new polymers and use of such polymers as a resin binder component for photoresist compositions, particularly chemically-amplified positive-acting resists that feature good solubility characteristics and can be effectively imaged at short wavelengths such as sub-300 nm, including 248 nm, 193 nm and especially 157 nm.

2. Background

Photoresists are photosensitive films used for transfer of images to a substrate. A coating layer of a photoresist is formed on a substrate and the photoresist layer is then exposed through a photomask to a source of activating radiation. The photomask has areas that are opaque to activating radiation and other areas that are transparent to activating radiation. Exposure to activating radiation provides a photoinduced chemical transformation of the photoresist coating to thereby transfer the pattern of the photomask to the photoresist-coated substrate. Following exposure, the photoresist is developed to provide a relief image that permits selective processing of a substrate.

A photoresist can be either positive-acting or negative-acting. For most negative-acting photoresists, those coating layer portions that are exposed to activating radiation polymerize or crosslink in a reaction between a photoactive compound and polymerizable reagents of the photoresist composition. Consequently, the exposed coating portions are rendered less soluble in a developer solution than unexposed portions. For a positive-acting photoresist, exposed portions are rendered more soluble in a developer solution while areas not exposed remain comparatively less developer soluble. Photoresist compositions are described in Deforest, Photoresist Materials and Processes, McGraw Hill Book Company, New York, ch. 2, 1975 and by Moreau, Semiconductor Lithography, Principles, Practices and Materials, Plenum Press, New York, ch. 2 and 4.

More recently, chemically-amplified-type resists have been increasingly employed, particularly for formation of sub-micron images and other high performance applications. Such photoresists may be negative-acting or positive-acting and generally include many crosslinking events (in the case of a negative-acting resist) or deprotection reactions (in the case of a positive-acting resist) per unit of photogenerated acid. In the case of positive chemically-amplified resists, certain cationic photoinitiators have been used to induce cleavage of certain “blocking” groups pendant from a photoresist binder, or cleavage of certain groups that comprise a photoresist binder backbone. See for example, U.S. Pat. Nos. 5,075,199; 4,968,581; 4,883,740; 4,810,613; and 4,491,628, and Canadian Patent -Application 2,001,384. Upon cleavage of the blocking group through exposure of a coating layer of such a resist, a polar functional group is formed, e.g., carboxyl or imide, which results in different solubility characteristics in exposed and unexposed areas of the resist coating layer. See also R. D. Allen et al., Proceedings of SPIE, 2724:334-343 (1996); and P. Trefonas et al. Proceedings of the 11th International Conference on Photopolymers (Soc. Of Plastics Engineers), pp 44-58 (Oct. 6, 1997).

While currently available photoresists are suitable for many applications, current resists also can exhibit significant shortcomings, particularly in high performance applications such as formation of highly resolved sub-half micron and sub-quarter micron features.

Consequently, interest has increased in photoresists that can be photoimaged with short wavelength radiation, including exposure radiation of about 250 nm or less, or even about 300 nm or less, such as wavelengths of about 248 nm (provided by KrF laser) or 193 nm (provided by an ArF exposure tool). See European Published Application EP915382A2. Use of such short exposure wavelengths can enable formation of smaller features. Accordingly, a photoresist that yields well-resolved images upon 248 nm or 193 nm exposure could enable formation of extremely small (e.g. sub-0.25 μm) features that respond to constant industry demands for smaller dimension circuit patterns, e.g. to provide greater circuit density and enhanced device performance.

However, many current photoresists are generally designed for imaging at relatively higher wavelengths, such as G-line (436 nm) and I-line (365 nm) are generally unsuitable for imaging at short wavelengths such as sub-300 nm. Even shorter wavelength resists, such as those effective at 248 nm exposures, also are generally unsuitable for sub-200 nm exposures, such as 193 and 157 nm imaging.

More specifically, current photoresists can be highly opaque to extremely short exposure wavelengths such as 157 nm, thereby resulting in poorly resolved images.

Additionally, cleavage of the blocking group alone has not always provided desired solubility characteristics in exposed and unexposed areas of the resist coating layer.

It thus would be desirable to have new photoresist compositions, particularly resist compositions that can be imaged at short wavelengths such as sub-300 nm exposure wavelengths, including 248 nm, particularly 193 nm and especially 157 nm. It would be further desirable to have new photoresist compositions that provide improved solubility characteristics.

### SUMMARY OF THE INVENTION

We have now found novel polymers and photoresist compositions that comprise the polymers as a resin binder component. The invention provides important advantages. For example, preferred photoresist compositions include base insoluble polymers with acid labile acetal and/or ketal groups. Such polymers can be cleaved by acid, thereby rending the polymer more base soluble. Preferred photoresists according to the invention provide highly resolved relief images upon exposure to extremely short wavelengths, particularly sub-300 nm wavelengths such as 248 mn, 193 nm and particularly 157 nmn.

Particular polymers of the invention include aromatic groups, such as phenyl, phenol, naphthylene, etc., or non-aromatic groups such an alicyclic group. Such polymers preferably include one or more electron-withdrawing groups, such as a halogen, nitro, cyano, nitrile, sulfinyl, sulfonyl, and the like. Halogen, particularly fluoro, are especially preferred groups. Additional examples of acceptable electronegative groups are provided below.

In particular, we have found that resins with an aromatic component and such electronegative substitution can exhibit good transparency at extremely short wavelengths such as 157 nm. Without being bound to theory, preferred electronegative according to the invention attract electrons from a variety of polymer or co-polymer bonds to facilitate a reduction or avoidance of light absorbance in the sub-300 nm range, particularly at 157 nm.

It is also been found that relatively base insoluble polymers can be rendered more soluble by including at least one acetal or ketal group in the polymer. Such a group when exposed to suitably acidic conditions becomes hydrolyzed, thereby cleaving the polymer at or near the group. The reaction makes the polymer more base soluble in many imaging applications. Preferred acetal or ketal groups provide for acid cleavage without compromising polymer stability in basic or neutral environments. As explained below, this feature of the invention helps to improve imaging e.g., by facilitating dissolution, transparency, resolution, depth of focus and contrast.

Significantly, the present invention now permits use of photoresists in the sub-300 nm range that include polymers with aromatic ring substituents or other absorbing groups. As will be appreciated, use of such polymers has been avoided due to unwanted light absorbance below 300 nm and particularly 157 nm. However as will be further appreciated, many aromatic ring substituents and especially phenolic rings and derivatives thereof provide photoresists with highly useful lithographic properties, such as resistance to plasma etchants and good substrate adherence.

Accordingly, the invention provides a range of polymers and co-polymers that can be controllably degraded into smaller polymeric or co-polymeric units, thereby enhancing base solubility in many applications. Such polymers and co-polymers can be used in a variety of photoresist compositions as the primary polymer component or as an additive as needed. In either case, such polymers provide significant advantages including increasing polymer dissolution characteristics, resolution, contrast, depth of focus, ect. and provide good imaging in the sub-300 nm range such as 197 nm and 157 nm.

By way of illustration, particular polymers of the invention include repeat units of divinyl, diphenol, diols, dithiols, alicyclic, cyclic alkyl and dicarboxylic acids such as those specified below. Preferred are polymers that include repeat units of a group that can form an acetal or ketal under polymerization or co-polymerization conditions such as those acid catalyzed polyaddition reactions typical of photoresist polymer synthesis strategies. An example of such a group is divinyl substituent that has a functional moiety capable of polymerizing or co-polymerizing with the diphenolic, diol, dithiol, alicyclic, cyclic alkyl or dicarboxylic groups to form the acetal or ketal. More preferred polymers include at least one electronegative group to help reduce or avoid unwanted light absorbance below 300 nm such as 197 nm and 157 nm.

For example, one polymer class of the invention is formed by co-polymerizing a divinyl ether group with a diphenolic, diol, dithiol, alicyclic, cyclic alkyl, or dicarboxylic acid. In one embodiment, hydrogen atoms on the divinyl ether group are substituted (fully or partially) with at least one of fluorine atom and/or fluorinated lower alkyl. The co-polymer thus formed features acceptable absorbance in the sub-300 nm range, particularly at 197 nm and 157 nm. As discussed, such polymers also include an acid labile acetal or ketal group that renders same significantly base soluble.

It will be appreciated that in some invention embodiments particular fluorination schemes may not be optimal. For example, there is recognition in the field that when a carbon atom is bonded to fluorine and hydroxyl, the fluorine reacts to produce hydrogen fluoride. Preferred practice of the invention will typically avoid such schemes to help maximize the stability of bonded fluorine atom.

More generally, there have been problems using many prior photoresists at sub-300 nm wavelengths. Resist absorbance at 157 nm has been a particular concern. For example, most current resists require a film thickness of at least about 100 nm to provide acceptable etch performance particularly when plasma etchants are used. At that thickness or greater however, transmittance of sub-300 nm wavelengths such as 157 nm is often too low for good resolution imaging. The invention addresses these problems by providing photoresists with acceptable 157 nm light absorbance even when provided as a film having at least about 50-100 nm thickness.

As discussed, there is a need in the field for more base soluble polymers, co-polymers and photoresist compositions that include same. The present invention addresses this need by providing a polymer or co-polymer backbone that can be acid cleaved at one or more pre-determined sites. Such sites are acid labile acetal or ketal groups that can be introduced into the polymer backbone as needed. Such photoresists exhibit acceptable sub-300 nm light absorbance and good base solubility when provided in a wide range of film thickness including those mentioned above.

More specifically, the invention provides novel polymers including at least one suitable electronegative group and photoresists comprising same that are capable of producing high-resolution images at less than 300 nm such as 193 nm and 157 nm. Such photoresists can be configured in film form having a thickness of at least about 50-100 nm, preferably about 350 nm to 400 nm. The photoresists of the invention are generally flexible and can be formulated as positive or negative chemically amplified photoresists as needed.

There is recognition that many current polymers useful as photoresists significantly absorb light below 300 nm. Without wishing to be bound to any theory, it is believed that by strategically adding one or more electronegative groups to such polymers, it is possible to substantially reduce or avoid unwanted light absorbance, particularly below 170 nm and especially 157 nm. As discussed below, more preferred electronegative groups generally include or consist of halogen, particularly fluoro, although other electronegative groups also will be suitable such as cyano, nitro, sulfinyl and sulfonyl. Particularly preferred electronegative groups within the scope of this invention are conjugated systems, particularly mono- or polycyclic aromatic systems such as phenyl, that are substituted by an electronegative group, particularly halogen, especially fluoro.

Other examples of preferred electronegative groups include fluorinated lower alkyl e.g, trifluoromethyl, trifluoroethyl, ect. Further examples of suitable electronegative groups are provided in the following discussion and examples.

The foregoing electronegative groups can be substituted for hydrogen atom nearly anywhere in the polymers or co-polymers provided herein such that unwanted light absorbance in the sub-300 nm range is reduced or avoided. For example, at least one of the electronegative groups, especially fluorine or fluorinated lower alkyl, can be substituted for hydrogen atom in one or more of the foregoing divinyl, diphenol, diol, dithiol, alicyclic, cyclic alkyl and dicarboxylic acid units. In this illustration of the invention, such substitution can be partial or total and include therefor polymers and co-polymers that are fully substituted with fluorine atom, fluorinated lower alkyl or both groups. As discussed, when fluorine atom is the electronegative group of choice, it is generally preferred to reduce or avoid presence of nearby reactive groups including hydroxyl bonded to the same atom as the fluorine.

Resists of the invention that contain a polymer as disclosed can produce highly resolved robust relief images particularly at 157 nm.

Accordingly, in one aspect, the invention provides polymers or co-polymers having the following distinct repeat units:

1) an optionally substituted divinyl unit comprising at least one functional group that forms an acetal or ketal group in a polymerization or co-polymerization reaction; and

2) an optionally substituted diphenol, diol, dithiol, alicyclic, cyclic alkyl or dicarboxylic acid unit that reacts with the divinyl unit to form the acetal or ketal group.

Preferably, at least one of the units specified in 1) and 2) above is substituted (fully or partially) with at least one electronegative group as defined herein. Typically, the electronegative group includes at least one electronegative atom, often halogen, usually less than about twenty (20) to thirty (30) of such atoms per unit. A particular halogen of interest is fluorine atom although in some invention embodiments, use of other halogen atoms may useful.

For example, in one invention embodiment, polymers and co-polymers comprising “mixed halogen” substitutions are provided e.g., substitutions with fluorine and chlorine atoms.

Preferred divinyl units according to the invention include one or more functional groups capable of forming the acetal or ketal groups in the polymer or co-polymer generally under trace acid catalysis conditions. An example of such a groups is a vinylic carbon atom, preferably bonded to oxygen, such as in a divinyl ether.

Without wishing to be bound by any theory, it is believed the combined use in polymers of the invention of i) the optionally substituted divinyl unit and ii) the optionally substituted divinyl, diphenol, diol, dithiol, alicyclic, cyclic alkyl or dicarboxylic acid units can help improve a range of photoresist properties including dissolution behavior, transparency, resolution, contrast, depth of focus, thermal flow temperature, scratch resistance, dry or wet etch characteristics and contrast. More specifically, these and other photoresist properties are positively impacted by including the polymers and co-polymers of this invention as the primary polymer or co-polymer or as an additive to help achieved desired properties.

In embodiments in which use of the polymer or co-polymer as an additive is indicated, the photoresist composition can include less than about 70% by weight of the polymer or co-polymer with from between about 10% to about 50% being preferred for many applications. Also contemplated is use of the polymers and co-polymers in bottom or top anti-reflection applications e.g., alone or as an admixture.

A significant advantage provided by the invention is the capacity to solubilize normally base insoluble polymers upon exposure to strong acid. Thus in embodiments in which the polymer or co-polymer includes the acetal or ketal group (or both groups), the strong acid preferably reacts with said groups and hydrolyzes them, thereby cleaving the polymer backbone into smaller units. Such smaller units (generally defined by the acetal or ketal group cleavage site) are significantly more soluble in base.

For example, in embodiments in which one or more photoacid generators are provided in the photoresist composition, exposure to strong acid degrades the polymer or co-polymer. When employed as a polymer additive, the invention thus provides for useful base development and significant removal of additive fragments at exposed regions. This feature of the invention provides a range of important advantages including improving imaging potential and particularly contrast.

In addition to the foregoing significant advantages, more preferred polymers and co-polymers disclosed herein include at least one electronegative group substituted for hydrogen atom, preferably fluorine or fluorinated lower alkyl. In this invention embodiment, a significant reduction in sub-300 nm wavelength absorbance can be achieved, particularly sub 170 nm and especially 157 nm while still imparting to the polymer a variety of desirable features including good resistance to plasma etchants. Such etch resistance can be critical to achieve desired results in high performance applications, e.g. forming highly resolved sub-half micron or sub-quarter micron resist features.

Illustrative divinyl, diphenol, diol, dithiol, and dicarboxylic acid units include those of current interest in positive- or negative-tone lithography. More specific examples of same are provided below. Preferred units include at least one electronegative group e.g., fluorine, fluorinated lower alkyl, fluorinated cyclic alkyl, fluorinated ethers and esters including cyclic molecules, to help achieve acceptable absorbance below 300 nm, particularly at 197 nm and 157 nm. Other suitable electronegative groups include halogenated cyclic alkyl, cyclic ethers and cyclic esters, particularly fluorinated compounds. More preferably, the units are fully substituted with fluorine atom and/or fluorinated lower alkyl to help optimize acceptable absorbance at 157 nm.

More particular polymers and co-polymers of the invention include one of the aforementioned units as a polymerized first repeat unit, and a polymerized second repeat unit. As discussed, a preferred polymerization reaction forms the acid labile acetal or ketal group within the polymer backbone. Typically, the first and second repeat units will be distinct from one another and include one or more electronegative groups the same or different.

For instance, the first divinyl repeat unit can be unsubstituted, and the second diphenol, diol, dithiol, or dicarboxylic acid repeat unit can have one or more of the foregoing electronegative groups, typically fluorine and/or fluorinated lower alkyl. Alternatively, the first divinyl repeat unit can include at least one of the electronegative groups, also typically fluorine and/or fluorinated lower alkyl. In another example, both the foregoing first and second repeat units each can have at least one electronegative groups, also typically fluorine atom and/or fluorinated lower alkyl. Each repeat unit can have the same electronegative groups or such groups may be different on each unit as needed. It is emphasized that the scope of the present invention is not limited to the aforementioned polymers and co-polymer units. That is, the invention can be usefully employed with a wide spectrum of polymers. As an example, it is possible to introduce acetal or ketal groups into a range of suitable polymers to provide that polymer with better base solubility. Such polymers can be further modified by introducing therein at least one electronegative group such as fluorine atom or fluorinated lower alkyl. Such groups help withdraw electrons from carbon-carbon bonds that absorb (or potentially absorb) below 300 nm, preferably below 170 nm and especially at 157 nm. The invention can thus be used to design new or improve existing polymers and photoresists having 1) unacceptable base solubility and/or 2) unsuitable light absorbance in the sub-300 nm range and especially at 197 nm and 157 nm.

In particular, for reducing light absorbance below 300 nm and particularly at 157 nm, the divinyl unit includes at least one of the electronegative groups previously mentioned as a hydrogen atom replacement. Such replacement however must not impact the capacity of the divinyl unit to form desired acetal or ketal groups in the polymer backbone.

Additionally, or in the alternative, unwanted light absorbance below 300 nm and particularly 157 nm can be reduced or avoided by including in the diphenol, diol, dithiol, or dicarboxylic acid group at least one of the electronegative groups previously mentioned as a hydrogen atom replacement. Such replacement must not interfere with ability of the unit to form the acetal or ketal groups when combined with the divinyl unit. Particular electronegative groups include those that include halogen, typically fluorine atom and fluorinated lower alkyl. Such groups can be the same or different from the electronegative group or groups on the divinyl unit.

The invention provides for more specific polymers and co-polymers that include one or more of the above features. For instance, preferred are tripolymers, tetrapolymers, pentapolymers, hexapolymers, septapolymers or other higher order polymers that contain at least the above groups 1) and 2) i.e. 1) (optionally substituted divinyl unit such divinyl ether); 2) (optionally substituted diphenol, diol, dithiol, or dicarboxylic acid group, such as diphenol ether or adamantyl dicarboxylic acid). To help reduce unwanted light absorption below 300 nm and particularly 157 nm, the divinyl unit preferably includes at least one halogen eg., fluorine atom or fluorinated lower alkyl.

Preferred polymers and co-polymer of the invention are rendered more base soluble by contact with strong acid and can be usefully employed in photoresists imaged at sub 300 nm, preferably below 170 nm, and especially at 157 nm. Accordingly, such resists will be substantially free of unsubstituted phenyl or other aromatic groups. In embodiments in which such groups are present including certain preferred phenolic or adamantyl polymers, such groups will include at least one suitable electronegative group such as a halogen atom or halogenated lower alkyl, preferably fluorine atom or fluorinated lower alkyl.

The invention also provides methods for forming relief images, including methods for forming a highly resolved relief image such as a pattern of lines where each line has essentially vertical sidewalls and a line width of about 0.40 microns or less, and even a width of about 0.25, 0.20 or 0.16 microns or less. The invention further provides articles of manufacture comprising substrates such as a microelectronic wafer substrate or liquid crystal display or other flat panel display substrate having coated thereon a polymer, photoresist or resist relief image of the invention.

Other aspects of the invention are disclosed infra.

### DETAILED DESCRIPTION OF THE INVENTION

Particular polymers and co-polymers of the invention include one or more repeat units that comprise at least one electronegative group which group typically includes an electronegative atom such as a halogen (F, Cl, Br, I). Fluorine is an especially preferred electronegative atom. In cases in which the electronegative group is halogen, usually less than about twenty five (25) atoms will be employed, preferably less than about twelve (12) of such atoms with less than about six (6) to nine (9) often being useful. Additionally preferred electronegative groups include lower alkyl and lower alkoxy that have been substituted (partially or fully) with halogen, typically fluorine with the provisio that bonded fluorine atoms are not made labile as discussed previously.

Preferred polymers of the invention are formed by combining a functional group of a divinyl compound with a corresponding reactive group on the diphenol, diol, dithiol, alicyclic, cyclic alkyl or carboxylic acid group. Each of said groups is optionally substituted with at least one electronegative group as defined herein. Generally, the reaction will be an acid catalyzed polyaddition between a vinylic carbon and a suitable hydroxyl, carboxylic or thiol sub stituent to form the desired labile acetal or ketal group. The divinyl group is bonded to hydrogen if it is a terminal group or bonded to a fragment of a suitable organic compound if it is a divalent internal group. Such vinyl compounds, including preferred divinyl ethers, may have one or more vinyl groups including more than one divinyl ether groups.

Typical vinyl ether compounds having a single vinyl ether group and suitable for purposes of the invention include, but are not limited to, compounds conforming to the following generic formula:

CH₂═CH—O—A—O—CH═CH₂

in which A represents a linear or branched cyclic or acyclic alkylene group having about 1 to about 10 carbon atoms in which A is optionally substituted with at least one electronegative group as defined herein e.g, fluorine atom, fluorinated lower alkyl, perfluoroalkyl, perfluoroalkylene, fluorinated cycloalkyl, and fluorinated ethers and esters including fluorinated cyclic ethers and esters.

More particular examples of such vinyl ethers include but are not limited to hydroxybutylvinyl ether, hexanediolmonovinyl ether, ethyleneglycolmonovinyl ether, butanediolmonovinyl ether, hexanediolmonovinyl ether, cylcohexanedimethanolmonovinyl ether, diethyleneglycolmonovinyl ether, etc. Compounds having two or more vinyl groups include 2-hydroxycyclohexane-1,6-dimethanol divinyl ether, 2-hydroxypropanediol-1,3-divinyl ether, 2-aminopropanediol-1,3-divinyl ether, 4-hydroxyheptanediol-1,4-divinyl ether, 4-aminoheptanediol-1,7-divinyl ether, perfluorocyclobutanol ether, perfluorbutanemethanol vinyl ether etc. Additional examples of vinyl ethers may be found in the above referenced EPO application 0 536 690.

More preferred vinyl ethers in accord with this invention are divinyloxyl compounds such as ethyleneglycol divinyl ether, divinyl ether, di(ethylene glycol) divinyl ether, tri(ethylene glycol) divinyl ether, 1,4-butanediol divinyl ether, 1,6-hexanediol divinyl ether.

Preferred examples of a polyaddition reaction between the foregoing vinyl ether and diphenol, diol, dithiol, or dicarboxylic acid compounds discussed above can be represented by the following reaction:

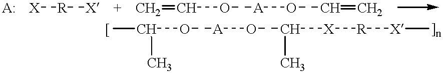

in which A is a linear or branched alkylene group having about 1 to about 10 carbon atoms in which A is optionally substituted with at least one electronegative group as defined herein e.g, fluorine atom and/or fluorinated lower alkyl,

each of X and X′ are each independently hydroxyl, carboxy, or thiol group, preferably X and X′ are the same,

R is an optionally substituted mono- or polycyclic carbon ring (aromatic or non-aromatic) having from between about five to about eighteen carbon atoms, preferably six to twelve of such carbon atoms; lower alkyl, or alicyclic group; and

n is about 1 to about 50, preferably about 20 to about 25.

Preferred carbon rings according to the above-mentioned reaction include, but are not limited to, diphenolic (in which the hydroxyl group is preferably in the para position) and diphenolic ether. Such rings can be optionally substituted with e.g., lower alkyl and/or lower alkoxy as needed.

Illustrative lower alkyl groups include methyl, ethyl, propyl, iso-propyl, butyl, iso-butyl, and t-butyl. Examples of suitable lower alkoxy groups include methoxy, ethoxy, proplyoxy, iso-propyloxy, butyloxy, iso-butyloxy, and t-butoxy.

Examples of alicycles include monocyclic and polycyclic molecules such as adamantine, norbomene, cyclohexane, cyclobutyl, dicyclohexane (preferably in which one ring is joined at the para position of the other ring).

It is an object of this invention to make polymers and co-polymers having acceptable light absorbance below 300 nm, particularly 197 nm and especially 157 nm. Accordingly, any of the foregoing compounds including specified divinyl, diphenol, diol, thiol, and dicarboxylic units will preferably include at least one electronegative group as defined herein, typically fluorine atom and/or fluorinated lower alkyl. Typically, the number of such groups on a polymer or co-polymer described herein will be guided by intended use and will include compounds in which each hydrogen atom has been replaced by an electronegative group such as fluorine atom and/or fluorinated lower alkyl.

The invention is compatible with use of other electonegative groups in addition to those specified herein. For example, groups that include fluorine atom may also comprise elements of monomers and polymer backbone. An example is provided by the following reaction:

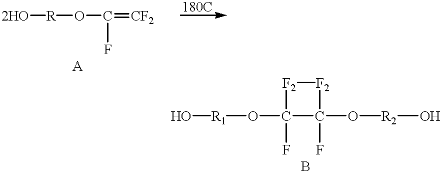

in which each of R, R₁, and R₂ is independently an optionally substituted phenyl, alkyl, alicyclic, fluorinated lower alkyl, or fluorinated alicyclic. In one embodiment, compound B above, can be reacted with vinyl ether to form particular polymers of this invention. In another embodiment, compound B can be converted to a divinyl ether and condensed with a bis hydroxy compound or a dicarboxylic acid to form a polymer.

Also preferred electronegative groups in accord with the invention include perfluoroalkyl, perfluoroalkylene, fluorinated cycloalkyl, and fluorinated ethers and esters including fluorinated cyclic ethers and esters.

Illustrative fluorinated lower alkyl groups in accord with the invention include, but are not limited to, trifluoromethyl, difluoromethyl, monofluoromethyl, pentafluoroethyl, tetrafluoroethyl, trifluoroethyl, diflouroethyl, monofluoroethyl and the like.

Additional particular electronegative groups include fluorinated acyclic such as fluorinated cyclopropyl and fluorinated cyclobutyl.

Examples of fluorinated loweralkoxy include trifluoromethoxy, difluoromethoxy, monofluoromethoxy, pentafluoroethoxy, tetrafluoroethoxy, trifluoroethoxy, difluoroethoxy, monofluoroethoxy and the like.

As mentioned, it will be useful in some invention embodiments to include at least one non-fluorine halogen such as chlorine as a substituent in the polymer or co-polymer. In this embodiment, the number of chlorine atom substitutions will be guided by intended polymer use but will generally be about the same as that provided for fluorine atom.

The polymers and co-polymers of the invention can be prepared by one or a combination of general strategies known in the field. For example, such compounds can be made by mixing the diphenol, diol, dithiol, or dicarboxylic acid compound with an equivalent amount of a vinyl compound at room temperature. Reaction times are from 3 to 24 hours and the compounds may be recovered by evaporation, all in accordance with conventional condensation procedures. See Examples 1 and 2 below for more specific information relating to making particular co-polymers.

As discussed, the invention also encompasses photoresist compositions that include the polymers and co-polymers disclosed herein. In one embodiment, the photoresists constitute from 65 to 98 percent by weight of the polymer or co-polymer solid, preferably, from 75 to 98 percent by weight of total solids and more preferably, from about 85 to 96 percent by weight of the solids. In another embodiment, the polymer and co-polymers are provided as an additive to e.g, a phenolic or other conventional resin the field, preferably less that about 70% of the total solids, more preferably between from about 10% to about 50% of the solids.

More particular photoresist compounds in accord with the invention include at least one photoactive compound such as those discussed in more detail below. Preferably, such a compound would comprise from about 2 to 20 percent by weight and preferably from 4 to 10 percent by weight. In addition to the resin binder and photoactive compound, the balance of the composition would comprise other components conventionally added to photoresists as would be known to those skilled in the art. Typical additives include surfactants, dyes, sensitizers, etc.

An objective of the invention is to provide new polymers that exhibit the required absorbance, dissolution characteristics and etching resistance necessary to produce a high resolution photoresist. In one aspect, the invention features polymers and photoresist compositions that include polymers functionalized with at least one electronegative group as defined herein, typically fluorine atom or fluorinated lower alkyl.

As discussed, the invention encompasses photoresist compositions (G/I-line, DUV, 193 nm and 157 nm) containing oligomers or polymers formed by the polyaddition of a divinyl ether and a diphenol, diol, dithiol or a dicarboxylic acid under trace acid catalysis in a non-interfering solvent. An important characteristic of these oligomers and polymers are their stability in basic (except possibly for the dicarboxylic acid derived materials) or neutral environments but readily degraded in the presence of a strong organic or mineral acid. As an additive to photoresist the oligomers or polymers may be used to reduce thermal flow temperature, improve scratch resistance (in PWB applications), improve dry or wet etch properties as well as contrast. In addition, these materials may also be used in bottom or top antireflection applications either alone or as an admixture. If a photoacid generator is also present in the composition then upon exposure a strong acid is produced that degrades the additive at the exposed region. Thus allowing base development and removal of the additive fragments at the exposed region. Examples of oligomers or polymers useful to the invention are shown in the following reactions I and II:

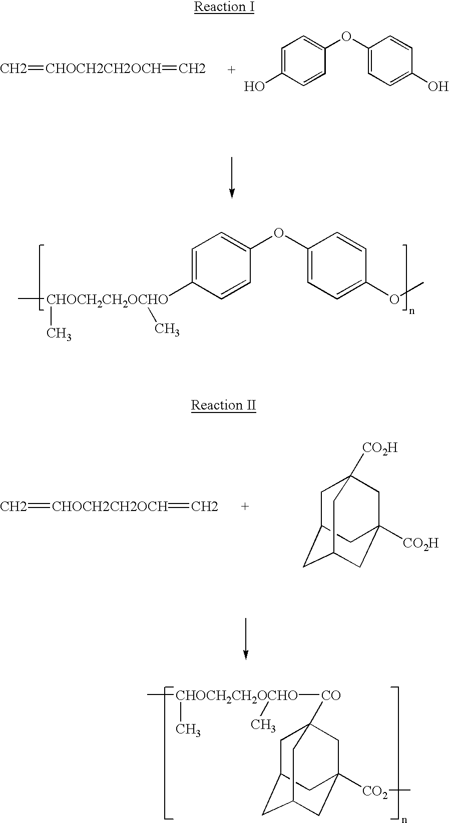

The divinyloxyl compounds may be, in addition to ethyleneglycol divinyl ether, divinyl ether, di(ethylene glycol) divinyl ether, tri(ethylene glycol) divinyl ether, 1,4-butanediol divinyl ether, or 1,6-hexanediol divinyl ether. Additional vinyl ethers that are also suitable are those of alicyclic diols. Many of the polyaddition oligomers and polymers are new compositions of matter.

More specific co-polymers of the invention are represented by the following Formula I:

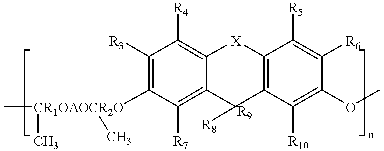

wherein each of R₁, R₂, R₃, R₄, R₅, R₆, R₇, R₈, R₉, and R₁₀ is independently -H or an electronegative group as defined herein e.g., fluorine, fluorinated lower alkyl, perfluoroalkyl, perfluoroalkylene, fluorinated cycloalkyl, and fluorinated ethers and esters including fluorinated cyclic ethers and esters the same or different,

A is a linear or branched alkylene group having 1 to 10 carbons atoms said alkylene

being optionally substituted with at least one of electronegative group as defined herein such as fluorine atom, fluorinated lower alkyl, perfluoroalkyl, perfluoroalkylene, fluorinated cycloalkyl, and fluorinated ethers and esters including fluorinated cyclic ethers and esters the same or different, or A is the same as X defined below and includes cyclic alkyl and phenyl,

X is oxygen atom, optionally substituted methylene including CF₂, or one of the following groups:

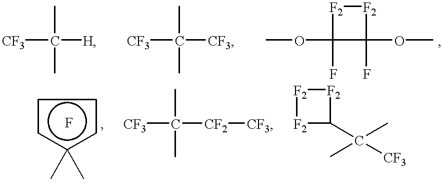

n is about 1 to about 50, preferably about 20 to about 25.

More specific polymers are represented by the following Formula II:

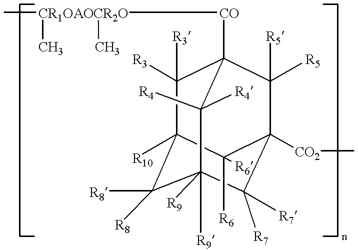

wherein each of R₁, R₂,R₃, R_{3′}, R₄, R_{4′}, R₅, R_{5′}, R₆, R_{6′}, R₇, R_{7′}, R₈, R_{8′}, R₉, R_{9′} and R₁₀ is independently, —H or an electronegative group as defined herein e.g., fluorine, fluorinated lower alkyl, perfluoroalkyl, perfluoroalkylene, fluorinated cycloalkyl, and fluorinated ethers and esters including fluorinated cyclic ethers and esters the same or different,

A is a linear or branched alkylene group having 1 to 10 carbons atoms said alkylene group being optionally substituted with at least one of an electronegative group as defined herein such as fluorine, fluorinated lower alkyl, perfluoroalkyl, perfluoroalkylene, fluorinated cycloalkyl, and fluorinated ethers and esters including fluorinated cyclic ethers and esters the same or different and n is about 1 to about 50, preferably about 20 to about 25.

Preferably, in both Formulae I and II above, the fluorinated lower alkyl is one of trifluoromethyl, difluoromethyl, monofluoromethyl, pentafluoroethyl, tetrafluoroethyl, trifluoroethyl, diflouroethyl, monofluoroethyl.

Also preferably, the fluorinated lower alkoxy in Formulae I and II above is trifluoromethoxy, difluoromethoxy, monofluoromethoxy, pentafluoroethoxy, tetrafluoroethoxy, trifluoroethoxy, difluoroethoxy, or a monofluoroethoxy group.

There is recognition in the field that most polymers and co-polymers absorb strongly at 157 nm. For example, polynorbomene, functionalized derivatives of which form thebasis of many 193 nm resist materials, exhibits an absorbance of 6.8 μm⁻¹. A resist for 248 nm applications, Shipley UV4, exhibits an absorbance value of 8.5 μm⁻¹, while polyethylene, a simple straight-chain hydrocarbon has an absorbance of 12.0 μm⁻¹. Clearly, it is not sufficient to exclude all π-electrons to control absorbance at 157 nm. On the contrary, the carbon backbone of the all-aliphatic polyethylene molecule, which is largely in the “all staggered” configuration functions quite effectively as a strong chromophore at 157 nm. Our “isolated molecule” calculations on decane indicate that, in this configuration, λₘₐₓ for the first excited singlet should occur at approximately 145-149 nm, very close to 157 nm. Matrix effects frequently lower the transition energy slightly (increase the wavelength). That being the case, the first singlet transition of the linear hydrocarbon, decane should exhibit a very strong absorbance at 157 nm.

It is believed that presence of one or more of the electronegative groups disclosed herein, particularly halogen and especially fluorine significantly reduces light absorbance in the sub-300 nm range particularly at 157 nm. Teflon AF®, a fully fluorinated polymer, has an absorbance of 0.70 μm⁻¹. By contrast with decane, above, perfluorodecane is predicted to exhibit a λₘₐₓ for the first excited singlet of about 201 nm. The second excited singlet is predicted to occur at 99 nm. Both of these absorption maxima are located far enough away from 157 nm so that PTFE, for example should have a relatively low absorbance. The present invention exploits electronegativity to desirably reduce absorbance at 157 nm. Preferred polymers and photoresist compositions also provide for good resist dissolution contrast, adhesion and etch resistance as discussed.

Additionally preferred photoresist compositions of the invention feature a sharp, clean solubility change during exposure and/or post-exposure-bake. This requirement is helpful. Gel formation at the developing front, typically facilitated by diffusion of water and developer ions into the resist matrix, produces a swollen, quasi-soluble material that will deform and cause delamination of resist features or limited resolution. In less severe cases, “micro-bridges” and other gum-like residues create defect issues.

By far, the most successful resist materials have been based on phenolic polymers, either cresol-formaldehyde novolak or polyhydroxystyrene. At their preferred wavelengths in the near UV or at 248 nm, respectively, these materials are quite transparent. Not to be overlooked, however, are the dissolution characteristics of these materials, which can be attributed to the relatively dense polymer matrix and the weakly acidic (pKₐj=9-10) phenolic proton. Together, these attributes prevent the diffusion of water and developer ions into the unexposed or lightly exposed polymer matrix with the result being crisp, high resolution resist images. Producing nanometer scale features requires even more stringent control over resist swelling.

Resists designed for 193 nm rely on carboxylic acids for their solubility because phenolic materials absorb too strongly at that wavelength. The initial resists swelled considerably in all but the most dilute developers. As a result, it was necessary to incorporate moieties into the polymer chain such as anhydrides and lactones that would undergo slow hydrolysis during development. By controlling developer diffusion in this way, high-resolution resist systems were made possible but at the expense of greater complexity.

As discussed, the invention provides polymers and co-polymers which can be functionalized to produce positive-tone resists substituted with e.g, fluorine atom or trifluoromethyl groups to avoid absorbing energy at 157 nm, thus taking advantage of the transparency “window” in the energy region between the transition to the second excited singlet and radiative ionization. These materials will offer low absorbance and permit use in conventional developers. Furthermore, it is believed that the enhanced fluorine content will reduce the surface tension in the developed resist, thereby reducing the tendency of the resist pattern to collapse during the rinse.

Initial studies of polymer materials at 157 nm indicate that one challenge to designing and building a high resolution resist is the absorbance of the polymer itself. Kunz has reported the absorbance of at least 32 types of “carbon backbone” polymer and 5 different siloxane backbone polymers.¹ According to that study, virtually all polymer materials tested, with the possible exception of Teflon AFT, which has an absorption coefficient of 0.70 μm⁻¹, exhibit high absorbance at 157 nm. Significantly, phenolic, acrylic, and entirely aliphatic polymers (e.g., polyethylene or polynorbomene) exhibit prohibitive absorbance.

As examples, the polymerized cyclic olefin, polynorbomene, has an absorbance coefficient of approximately 6.8 μm⁻¹ while polyethylene has an absorbance coefficient of 12.0 μm⁻¹. Without wishing to be bound to theory, it is believed that the carbon backbone itself functions as a chromophore at 157 nm. It is further believed that the first singlet electronic transitions for gas-phase decane and norbomane occur at 8.32-8.57 eV and 8.53-8.59 eV, respectively, are very close to the 7.89 eV 157 nm photon energy. It is estimated that in the solid polymer phase, the energies of these transitions will be lowered by approximately 0.3-0.5 eV so as to coincide even more closely with the photon energy.

As discussed, it is an object of this invention to provide phenolic resists having good absorbance characteristics below 300 nm and particularly 157 nm. Resists containing phenolic moieties can be employed at 157 nm, provided that they have the proper substitution of electron withdrawing groups. In a particular invention embodiment, phenols substituted with trifluoromethyl groups can be used to avoid significant absorption at 157 nm. Without wishing to be bound to theory, such sources of absorption can arise either from the excitation of the phenolic moiety to the second excited singlet state or the ionization of the polymer. In either case, the polymer would absorb strongly.

Polymers of the invention can be prepared by a variety of methods. One suitable method involves an acid catalyzed addition reaction such as those reactions known in the field. More specific reaction conditions can be found in the Examples.

More preferred reaction conditions involve trace acid catalysis substantially free of any interfering solvents.

As discussed, various moieties may be optionally substituted. A “substituted” substituent may be substituted at one or more available positions, typically 1, 2, or 3 positions by one or more suitable groups such as e.g. halogen (particularly F, Cl or Br); C₁₋₈ alkyl; C₁₋₈ alkoxy; C₂₋₈ alkenyl; C₂₋₈ alkynyl; hydroxyl; alkanoyl such as a C₁₋₆ alkanoyl e.g. acyl and the like; etc.

More specific substitutions in accord with the invention are fluorine atom, fluorinated lower alkyl, perfluoroalkyl, perfluoroalkylene, fluorinated cycloalkyl, and fluorinated ethers and esters including fluorinated cyclic ethers and fluorinated cyclic esters.

Preferably a polymer of the invention will have a weight average molecular weight (Mw) of about 800 or 1,000 to about 100,000, more preferably about 2,000 to about 30,000, still more preferably from about 2,000 to 15,000 or 20,000, with a molecular weight distribution (Mw/Mn) of about 5 or less, more preferably a molecular weight distribution of about 2 or less. Molecular weights (either Mw or Mn) of the polymers of the invention are suitably determined by gel permeation chromatography.

Polymers of the invention used in photoresist formulations should contain a sufficient amount of photogenerated acid labile ester groups to enable formation of resist relief images as desired. For instance, suitable amount of such acid labile ester groups will be at least 1 mole percent of total units of the polymer, more preferably about 2 to 40, 50, 60 or 70 mole percent, still more typically about 3 to 30, 40, 50, 60 or 70 mole percent of total polymer units. See the examples which follow for exemplary preferred polymers.

As discussed above, the polymers of the invention are highly useful as a resin binder component in photoresist compositions, particularly chemically-amplified positive resists. Photoresists of the invention in general comprise a photoactive component and a resin binder component that comprises a polymer as described above.

The resin binder component should be used in an amount sufficient to render a coating layer of the resist developable with an aqueous alkaline developer.

The resist compositions of the invention also comprise a photoacid generator (i.e. “PAG”) that is suitably employed in an amount sufficient to generate a latent image in a coating layer of the resist upon exposure to activating radiation. Preferred PAGs for imaging at 193 nm and 248 nm imaging include imidosulfonates such as compounds of the following formula:

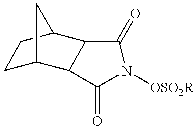

wherein R is camphor, adamantane, alkyl (e.g. C₁₋₁₂ alkyl) and perfluoroalkyl such as perfluoro(C₁₋₁₂ alkyl), particularly perfluorooctanesulfonate, perfluorononanesulfonate and the like. A specifically preferred PAG is N-[(perfluorooctanesulfonyl)oxy]-5-norbomene-2,3-dicarboximide.

Sulfonate compounds are also suitable PAGs, particularly sulfonate salts. Two suitable agents for 193 mn and 248 nm imaging are the following PAGS 1 and 2:

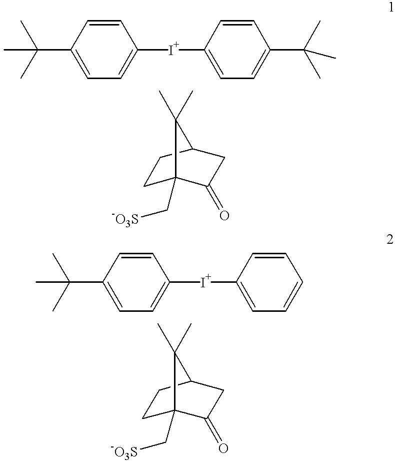

Such sulfonate compounds can be prepared as disclosed in European Patent Application 96118111.2 (publication number 0783136), which details the synthesis of above PAG 1.

Also suitable are the above two iodonium compounds complexed with anions other than the above-depicted camphorsulfonate groups. In particular, preferred anions include those of the formula RSO₃— where R is adamantane, alkyl (e.g. C₁₋₁₂ alkyl) and perfluoroalkyl such as perfluoro (C₁₋₁₂ alkyl), particularly perfluorooctanesulfonate, perfluorobutanesulfonate and the like.

Other known PAGS also may be employed in the resists of the invention.

Particularly for 193 nm and 157 nm imaging, generally preferred are PAGS that do not contain aromatic groups, such as the above-mentioned imidosulfonates, in order to provide enhanced transparency.

Photoacid generators will be selected for such factors as absorbance, quantum efficiency, outgassing during exposure and acid strength. By far, the most promising class of photoacid generators at 157 nm comprises the “onium” salts. These materials frequently have lower than expected absorbance and are usually present in the resist at levels less than 5% by weight of solids. These materials consist of combinations of independently variable cations and anions that include the following:

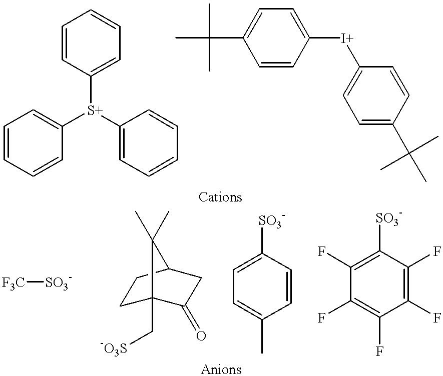

The choice of photoacid generator affects out-gassing of the resist during exposure, not only because of the direct photolysis products from the PAG decomposition but because stronger acids tend to make the deprotection traction more facile. The choice of PAG will depend strongly on its influence on out-gasing.

Other PAGs can be used with the present invention. Fortunately, Kunz et al. have shown that “onium” salt PAG materials are relatively low in absorbance.¹ Since PAGs are usually present at low concentration, they should not contribute significantly to the overall absorbance of the resist. Typical PAG cations and anions include the following:

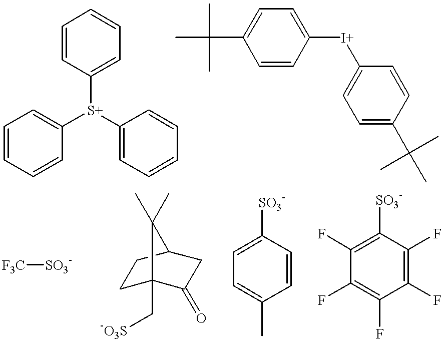

A preferred optional additive of resists of the invention is an added base, particularly tetrabutylammonium hydroxide (TBAH), or tetrabutylammonium lactate, which can enhance resolution of a developed resist relief image. For resists imaged at 193 nm, a preferred added base is a hindered amine such as diazabicyclo undecene or diazabicyclononene. The added base is suitably used in relatively small amounts, e.g. about 0.03 to 5 percent by weight relative to the total solids.

Photoresists of the invention also may contain other optional materials. For example, other optional additives include anti-striation agents, plasticizers, speed enhancers, etc. Such optional additives typically will be present in minor concentrations in a photoresist composition except for fillers and dyes which may be present in relatively large concentrations, e.g., in amounts of from about 5 to 30 percent by weight of the total weight of a resist's dry components.

The resists of the invention can be readily prepared by those skilled in the art. For example, a photoresist composition of the invention can be prepared by dissolving the components of the photoresist in a suitable solvent such as, for example, ethyl lactate, ethylene glycol monomethyl ether, ethylene glycol monomethyl ether acetate, propylene glycol monomethyl ether; propylene glycol monomethyl ether acetate and 3-ethoxyethyl propionate. Typically, the solids content of the composition varies between about 5 and 35 percent by weight of the total weight of the photoresist composition. The resin binder and photoactive components should be present in amounts sufficient to provide a film coating layer and formation of good quality latent and relief images.

The compositions of the invention are used in accordance with generally known procedures. The liquid coating compositions of the invention are applied to a substrate such as by spinning, dipping, roller coating or other conventional coating technique. When spin coating, the solids content of the coating solution can be adjusted to provide a desired film thickness based upon the specific spinning equipment utilized, the viscosity of the solution, the speed of the spinner and the amount of time allowed for spinning.

The resist compositions of the invention are suitably applied to substrates conventionally used in processes involving coating with photoresists. For example, the composition may be applied over silicon wafers or silicon wafers coated with silicon dioxide for the production of microprocessors and other integrated circuit components. Aluminum-aluminum oxide, gallium arsenide, ceramic, quartz, copper, glass substrates and the like are also suitably employed.

Following coating of the photoresist onto a surface, it is dried by heating to remove the solvent until preferably the photoresist coating is tack free. Thereafter, it is imaged through a mask in conventional manner. The exposure is sufficient to effectively activate the photoactive component of the photoresist system to produce a patterned image in the resist coating layer and, more specifically, the exposure energy typically ranges from about 1 to 100 mJ/cm², dependent upon the exposure tool and the components of the photoresist composition.

As discussed above, coating layers of the resist compositions of the invention are preferably photoactivated by a short exposure wavelength, particularly a sub-300 and sub-300 nm exposure wavelength, and even sub-170 nm wavelength. As discussed above, 157 nm is a particularly preferred exposure wavelength. However, the resist compositions of the invention also may be suitably imaged at higher wavelengths. For example, a resin of the invention can be formulated with an appropriate PAG and a sensitizer if needed and imaged at higher wavelengths such as about 193 nm or 248 nm.

Following exposure, the film layer of the composition is preferably baked at temperatures ranging from about 70° C. to about 160° C. Thereafter, the film is developed. The exposed resist film is rendered positive working by employing a polar developer, preferably an aqueous based developer such as quaternary ammonium hydroxide solutions such as a tetra-alkyl ammonium hydroxide solution; various amine solutions preferably a 0.26 N tetramethylammonium hydroxide, such as ethyl amine, n-propyl amine, diethyl amine, di-n-propyl amine, triethyl amine, or methyldiethyl amine; alcohol amines such as diethanol amine or triethanol amine; cyclic amines such as pyrrole, pyridine, etc. In general, development is in accordance with procedures recognized in the art.

Following development of the photoresist coating over the substrate, the developed substrate may be selectively processed on those areas bared of resist, for example by chemically etching or plating substrate areas bared of resist in accordance with procedures known in the art. For the manufacture of microelectronic substrates, e.g., the manufacture of silicon dioxide wafers, suitable etchants include a gas etchant, e.g. a halogen plasma etchant such as a chlorine or fluorine-based etchant such a Cl₂ or CF₄/CHF₃ etchant applied as a plasma stream. After such processing, resist may be removed from the processed substrate using known stripping procedures.

All documents mentioned herein are incorporated herein by reference. The following non-limiting examples are illustrative of the invention.

### EXAMPLE 1

### Acid-catalyzed Addition Copolymerization of Ethylene Glycol Divinyl Ether (EGDE) and Dihydroxy Phenyl Ether (DHPE)

In a 100 mL three-neck round bottom flask were added 3.54 g (17.52 mmol) of dihydroxy phenyl ether (DHPE), 2.00 g (17.52 mmol) of ethylene glycol divinyl ether (EGDE), and 7 mL of dry tetrahydrofuran (THF). The reaction vessel was then purged with nitrogen and the reaction mixture was kept under inert atmosphere. A catalytic amount (ca. 0.1 mL) of trifluoroacetic acid (TFA) was added and the reaction mixture was stirred for 24 h at 22° C. An excess amount (ca. 0.5 mL) of EGDE was added to the reaction mixture and stirred for 2 h. The reaction mixture was neutralized with sodium ethoxide-ethanol solution. The solution was precipitated in 400 mL of deionized water and stirred for an hour. Sticky white precipitate was then washed with 400 mL of deionized water with stirring. Overnight air-drying gave 3.46 g of white solid (63% yield) and the product is being dried under vacuum at 25° C.

The foregoing EGDE and DHPE co-polymer can be employed in many photoresist applications intended for 240 nm imaging. For effective imaging at shorter light wavelength such as below 300 nm and especially 194 nm and 157 nm, hydrogen atoms in the co-polymer can be substituted with electronegative groups such as fluorine atom and/or fluorinated lower alkyl. Fully substituted co-polymer will be especially useful for 157 nm applications in which minimal light absorbance is desired.

### EXAMPLE 2

### Acid-catalyzed Addition Copolymerization of Ethylene Glycol Divinyl Ether (EGDE) and 4,4′-(hexafluoroisopropylidene)-diphenol

In a 100 ml three-neck round bottom flask were added 2.95 g (8.76 mmol) of 4,4′-(hexafluoro-isopropylidene)-dephenol, 1.00 g (8.76 mmol) of ethylene glycol divinyl ether (EGDE), and 5 ml of dry tetrahydrofuran (THF). The reaction vessel was then purged with nitrogen and the reaction mixture was kept under inert atmosphere. A catalytic amount (ca. 0.1 ml) of trifluoracetic acid was added and the reaction mixture was stirred for 24 hr at 22° C. An excess amount (ca. 0.5 ml) of EGDE was added to the reaction misxture and stirred for an hour. The reaction mixture was divided into two parts, one of which sas neutralized with sodium ethoxide-ethanol solution. The other part was treated with ammonium hydroxide. Both THF solutions were precipitated in 400 ml of deionized water, respectively, and stirred for an hour. Sticky white precipitate was then washed with 400 ml of deionized water, with stirring and air-dried for an hour. Vacuum dring for 48 hrs at 25° C. gaove 1.94 g (NaOEt treated) and 1.57 g (NH₄OH treated) of white solid. Overall yield: 89%. Molecular weight: M_{w} 9300 Mₙ 4400 PD 2.11 (NaOEt treated), M_{w} 7900 Mₙ 3900 PD 2.01 (NH₄OH treated).

The foregoing description of the invention is merely illustrative thereof, and it is understood that variations and modifications can be effected without departing from the spirit or scope of the invention as set forth in the following claims.

All publications disclosed herein are incorporated by reference.

What is claimed is:

1. A method for forming a photoresist relief image, comprising:
(a) applying a photoresist composition on a substrate, the photoresist comprising a resin and a photoactive component, the resin comprising at least one acetal or ketal group,
(b) exposing the photoresist composition to conditions sufficient to generate acid, the acid being sufficient to hydrolyze the acetal or ketal group and cleave the resin; and
(c) exposing the photoresist to activating radiation and developing the exposed photoresist layer.

2. The method of claim 1, wherein the resin comprises at least one electronegative group and the photoresist is exposed with radiation having a wavelength of less than about 300 nm.

3. The method of claim 2, wherein the photoresist is exposed with radiation having a wavelength of less than about 260 nm.

4. The method of claim 2, wherein the photoresist is exposed with radiation having a wavelength of less than about 200 nm.

5. The method of claim 2, wherein the photoresist is exposed with radiation having a wavelength about 157 nm.

6. The method of any one of claims 1 through 5 wherein the resin comprises phenolic units.

7. The method of any one of claims 1 through 6 wherein the resin comprises halogen, halogenated lower alkyl, nitro, cyano, sulfinyl, O—C—O or sulfonyl groups.

8. The method of any one of claims 1 through 7 wherein the resin comprises at least one of fluorine atom, fluorinated lower alkyl, perfluoroalkyl, perfluoroalkylene, fluorinated cycloalkyl, and fluorinated ethers and esters including fluorinated cyclic ethers and esters.

9. The method of any one of claims 1 through 8 wherein the polymer is a novolak.

10. The method of any one of claims 1 through 9 wherein the polymer comprises acrylate units.

11. The method of any one of claims 1 through 10 wherein the polymer is chemically amplified positive resist.

12. The method of any one of claims 1 through 10 wherein the polymer is a negative resist.

13. A photoresist composition comprising a photoactive component and a resin binder comprising a polymer that comprises repeat units of:
1) a divinyl unit comprising at least one functional group that forms an acetal or ketal group in a polymerization or co-polymerization reaction; and
2) a diphenol, diol, dithiol, alicyclic, cyclic alkyl or dicarboxylic acid unit that reacts with the divinyl unit to form the acetal or ketal group.

14. The photoresist composition of claim 13, wherein the polymer further comprises at least one electronegative group substituted for hydrogen atom on the divinyl unit.

15. The photoresist composition of claims 13 and 14, wherein the polymer comprises at least one electronegative group substituted for hydrogen atom on the diphenol, diol, dithiol, or dicarboxylic acid unit.

16. The photoresist of claims 13-15, wherein the electronegative group is one of halogen, halogenated lower alkyl, nitro, cyano, sulfinyl, O—C—O, or sulfonyl groups.

17. The method of any one of claims 13-16, wherein the resin comprises at least one of fluorine atom or fluorinated lower alkyl.

18. The photoresist of claims 1-17, wherein the polymer is a co-polymer.

19. The photoresist of claims 1-18, wherein the polymer comprises polymerized diphenolic, adamantyl dicarboxylic, or ethylene units.

20. The photoresist of any one of claims 13 through 19 wherein the first electronegative group is one of halogen, halogenated lower alkyl, CN, or O—C—O.

21. The photoresist of claim 20 wherein the halogen is fluorine.

22. The photoresist of claims 2-21, wherein the electronegative group is one of fluorine atom, trifluoromethyl, difluoromethyl, monofluoromethyl, pentafluoroethyl, tetrafluoroethyl, trifluoroethyl, diflouroethyl, monofluoroethyl, trifluoromethoxy, difluoromethoxy, monofluoromethoxy, pentafluoroethoxy, tetrafluoroethoxy, trifluoroethoxy, difluoroethoxy, or a monofluoroethoxy group.

23. The photoresist of claim 2 wherein the polymer comprises units of the following Formula I: 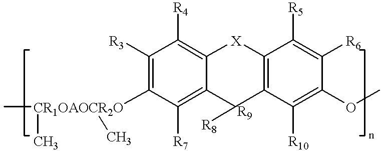
wherein each of R₁, R₂, R₃, R₄, R₅, R₆, R₇, R₈, R₉, and R₁₀ is independently —H or an electronegative group as defined herein e.g., fluorine, fluorinated lower alkyl, perfluoroalkyl, perfluoroalkylene, fluorinated cycloalkyl, and fluorinated ethers and esters including fluorinated cyclic ethers and esters the same or different,
A is a linear or branched alkylene group having 1 to 10 carbons atoms said alkylene
being optionally substituted with at least one of electronegative group as defined herein such as fluorine atom, fluorinated lower alkyl, perfluoroalkyl, perfluoroalkylene, fluorinated cycloalkyl, and fluorinated ethers and esters including fluorinated cyclic ethers and esters the same or different, or A is the same as X defined below and includes cyclic alkyl and phenyl,
X is oxygen atom, optionally substituted methylene including CF₂, or one of the following groups: 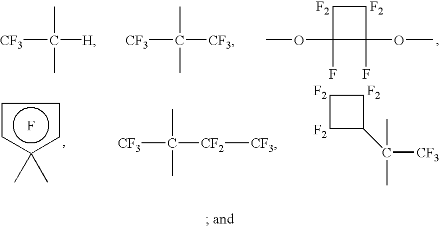
n is about 1 to about 50, preferably about 20 to about 25.

20. The photoresist of claim 2, wherein the polymer has the following Formula II: 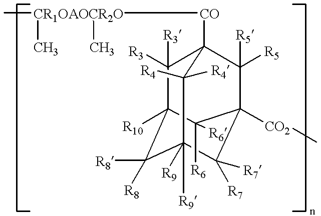
wherein each of R₁, R₂, R₃, R_{3′}, R₄, R_{4′}, R₅, R₅₋, R₆, R_{6′}, R₇, R_{7′}, R₈, R_{8′}, R₉, R_{9′} and R₁₀ is independently, —H or an electronegative group as defined herein e.g., fluorine, fluorinated lower alkyl, perfluoroalkyl, perfluoroalkylene, fluorinated cycloalkyl, and fluorinated ethers and esters including fluorinated cyclic ethers and esters the same or different,
A is a linear or branched alkylene group having 1 to 10 carbons atoms said alkylene group being optionally substituted with at least one of an electronegative group as defined herein such as fluorine, fluorinated lower alkyl, perfluoroalkyl, perfluoroalkylene, fluorinated cycloalkyl, and fluorinated ethers and esters including fluorinated cyclic ethers and esters the same or different and n is about 1 to about 50, preferably about 20 to about 25.

21. The photoresist of claim 19 or 20 wherein the fluorinated lower alkyl is one of trifluoromethyl, difluoromethyl, monofluoromethyl, pentafluoroethyl, tetrafluoroethyl, trifluoroethyl, diflouroethyl, monofluoroethyl, trifluoromethoxy, difluoromethoxy, monofluoromethoxy, pentafluoroethoxy, tetrafluoroethoxy, trifluoroethoxy, difluoroethoxy, or a monofluoroethoxy group.

22. A method of forming a positive or negative photoresist relief image, comprising:
(a) applying a coating layer of a photoresist of any one of claims 1-21 on a substrate; and
(b) exposing and developing the photoresist layer to yield a relief image.

23. The method of claim 22 wherein the photoresist layer is exposed with radiation having a wavelength of less than about 300 nm.

24. The method of claim 23 wherein the photoresist layer is exposed with radiation having a wavelength of about 170 nm.

25. The method of claim 22 wherein the photoresist layer is exposed with radiation having a wavelength of about 157 nm.

26. An article of manufacture comprising a substrate having coated thereon a layer of the photoresist composition of any one of claims 1-25.

27. The article of claim 26 wherein the substrate is a microelectronic wafer or an optical-electronic device substrate.
